(19) United States
(12) Patent Application Publication
(10) Pub. No.: US 2010/0105198 A1
(43) Pub. Date: Apr. 29, 2010

(54) Gate Electrode of semiconductor device and method of forming the same

(76) Inventors: Sang-woo Lee, Seoul (KR); Gil-heyun Choi, Seoul (KR); Chang-won Lee, Gwacheon-si (KR); Byung-hee Kim, Seoul (KR); Jin-ho Park, Yongin-si (KR); Eun-ji Jung, Suwon-si (KR); Jeong-gil Lee, Goyang-si (KR)

Correspondence Address: LEE & MORSE, P.C., 3141 FAIRVIEW PARK DRIVE, SUITE 500, FALLS CHURCH, VA, 22042, US

(21) Appl. No.: 12/458,767

(22) Filed: Jul. 22, 2009

(30) Foreign Application Priority Data
Oct. 28, 2008 (KR) 10-2008-0105922

(51) Int. Cl. H01L 21/336

(52) U.S. Cl. 438/586; 257/E21.423

(57) ABSTRACT

A method of forming a gate electrode of a semiconductor device includes forming a first polysilicon layer in a peripheral circuit region of a substrate, forming a barrier layer on the first polysilicon layer, the barrier layer providing an ohmic contact, forming a stack structure including a tunneling insulation layer, an electric charge storing layer, and a blocking insulation layer in a memory cell region of the substrate, forming a second polysilicon layer on the barrier layer and the blocking insulation layer, and siliciding the second polysilicon layer and forming a silicide gate electrode.

### BACKGROUND

1. Field

Embodiments relate to a semiconductor device and, more particularly, to a method of forming a gate electrode of a semiconductor device.

2. Description of the Related Art

As integration of semiconductors increases, a designing rule has become strict and a critical dimension has been reduced in the semiconductors. As a result, a wiring resistance and a contact resistance are gradually increased and such increases cause deterioration in operation and performance of the semiconductor devices. Thus, to improve the wiring resistance and contact resistance, a silicide film is formed on a gate electrode and a source/drain region of a semiconductor device using a self alignment method.

### SUMMARY

Embodiments are therefore directed to a method of forming a gate electrode of a semiconductor device, which substantially overcome one or more of the problems due to the limitations and disadvantages of the related art.

It is therefore a feature of an embodiment to provide a gate electrode of a semiconductor device that can decrease a resistance of the gate electrode, thereby increasing an operation speed of the memory cells.

At least one of the above and other features and advantages may be realized by providing a method of forming a gate electrode of a semiconductor device, the method including forming a first polysilicon layer in a peripheral circuit region of a substrate, forming a barrier layer on the first polysilicon layer, the barrier layer providing an ohmic contact, forming a stack structure including a tunneling insulation layer, an electric charge storing layer, and a blocking insulation layer in a memory cell region of the substrate, forming a second polysilicon layer on the barrier layer and the blocking insulation layer, and siliciding the second polysilicon layer and forming a silicide gate electrode.

The forming of the silicide gate electrode may include forming a full silicide gate electrode in the memory cell region and forming a partial silicide gate electrode in the peripheral circuit region.

The method may further include forming a plurality of memory cells by patterning the second polysilicon layer, the blocking insulation layer, the electric charge storing layer, and the tunneling insulation layer formed in the memory cell region.

The forming of the full silicide gate electrode may include forming a metal layer on the plurality of memory cells, and heat-treating the metal layer and forming the full silicide gate electrode by a reaction between the second polysilicon layer and the metal layer.

The heat-treating of the metal layer and forming of the full silicide gate electrode by a reaction between the second polysilicon layer and the metal layer may include first heat-treating the metal layer at temperature of about 250° C. to about 550° C., removing the metal layer that does not react in the first heat-treating, and second heat-treating the metal layer at temperature of about 400° C. to about 850° C. and thereby forming the full silicide gate electrode by a reaction between the second polysilicon layer and the metal layer.

The metal layer that does not react in the first heat-treating may include portions that are on the substrate between adjacent memory cells as well as a portion on the substrate between the memory cell and the peripheral circuit region.

The forming of the partial silicide gate electrode may include forming a metal layer on the second polysilicon layer formed in the peripheral circuit region, and heat-treating the metal layer and forming the partial silicide gate electrode by a reaction between the second polysilicon layer and the metal layer.

The barrier layer may include metal nitride or tungsten silicide (WSiₓ).

The method may further include a third polysilicon layer on the barrier layer to prevent etching of the barrier layer.

The method may further include performing an oxidation process by filling spaces between the plurality of memory cells with oxides, and removing the oxides.

The method may further include performing the oxidation process before siliciding the second polysilicon layer.

The electric charge storing layer may include SiN, the blocking insulation layer may include at least one of Al₂O₃, ZrO₂, and HfO₂, and the metal layer may include at least one of Ti, W, Co, Ni, Pt, and Re.

At least one of the above and other features and advantages may also be realized by providing a semiconductor device having a substrate, the substrate including a memory cell region and a peripheral circuit region, a plurality of memory cells in the memory cell region, each memory cell having a stack structure and a silicide layer, and at least one transistor in the peripheral circuit region, wherein the silicide layer operates as a control gate.

The stack structure may include a tunneling insulation layer, an electric charge storage layer, and a blocking insulation layer.

The at least one transistor may include a polysilicon layer, a barrier layer and the silicide layer.

The barrier layer may include a metal nitride or tungsten silicide (WSiₓ).

At least one of the above and other features and advantages may also be realized by providing a memory system, including a memory device, and a memory controller electrically coupled to the memory device, wherein the memory device includes, a substrate including a memory cell region and a peripheral circuit region, a plurality of memory cells in the memory cell region, each memory cell having a stack structure and a silicide layer, and at least one transistor in the peripheral circuit region, wherein the silicide layer operates as a control gate.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 through 9 illustrate cross-sectional diagrams of stages in a method of forming a gate electrode of a semiconductor device according to an embodiment;

FIG. 10 illustrates a silicide layer formed in a peripheral circuit region when SiN is used to form a barrier layer;

FIG. 11 illustrates a silicide layer formed in a peripheral circuit region when SiO₂ is used to form a barrier layer;

FIG. 12 illustrates a silicide layer formed in a peripheral circuit region when WSiₓ is used to form a barrier layer;

FIG. 13 illustrates a cross-sectional diagram of a semiconductor device according to an embodiment;

FIG. 14 illustrates a flowchart showing a method of forming a gate electrode of a semiconductor device according to an embodiment;

FIG. 15 schematically illustrates a card according to an embodiment; and

FIG. 16 schematically illustrates a system according to an embodiment.

### DETAILED DESCRIPTION

Korean Patent Application No. 10-2008-0105922, filed on Oct. 28, 2008, in the Korean Intellectual Property Office, and entitled: “Method of Forming Gate Electrode of Semiconductor Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

It will be understood that when an element such as a layer, a region, or a substrate is referred to as being “formed on,” “connected with,” or “coupled to” another element, it can be directly “formed on” “connected with,” or “coupled to” other element or intervening elements may be present. In contrast, when an element is referred to as being “directly formed on,” “directly connected with,” or “directly coupled to” another, there are no intervening elements. Like numbers refer to like elements throughout the description of the figures. It will be further understood that the term “and/or” includes any and all combinations of one or more of the associated listed items.

It will be understood that, although the terms first, second, etc. may be used herein to describe various elements, components, regions, layers, and/or parts, these elements, components, regions, layers, and/or parts should not be limited by these terms. These terms are only used to distinguish one element, component, region, layer, and/or part from another. Accordingly, a first element, component, region, layer, and/or part could be termed a second element, component, region, layer, and/or part, without departing from the scope of example embodiments.

Moreover, the relative terms “on,” “above,” “below,” “under” can be used to describe the relationship between the elements illustrated in the drawings. It can be understood that these relative terms are added to describe the directions of the elements and intend to include other directions of the elements. For example, when the element is turned over in the drawings, the elements described as being present on the upper surface of other elements may have directions on the lower surface of other elements. For example, the term “on” may include all directions “below” and “on” depending on a specific direction of the drawings. If the elements face other direction (rotated by 90 degrees with respect to the other direction), relative descriptions used herein may be interpreted based on this.

The terminology used herein is for the purpose of describing particular embodiments only and is not intended to be limiting of example embodiments. As used herein, the singular forms are intended to include the plural forms as well, unless the context clearly indicates otherwise. It will be further understood that the terms “comprises,” and/or “comprising,” when used herein, specify the presence of stated features, integers, steps, operations, elements, components, and/or groups but do not preclude the presence or addition of one or more other features, integers, steps, operations, elements, components, and/or groups thereof.

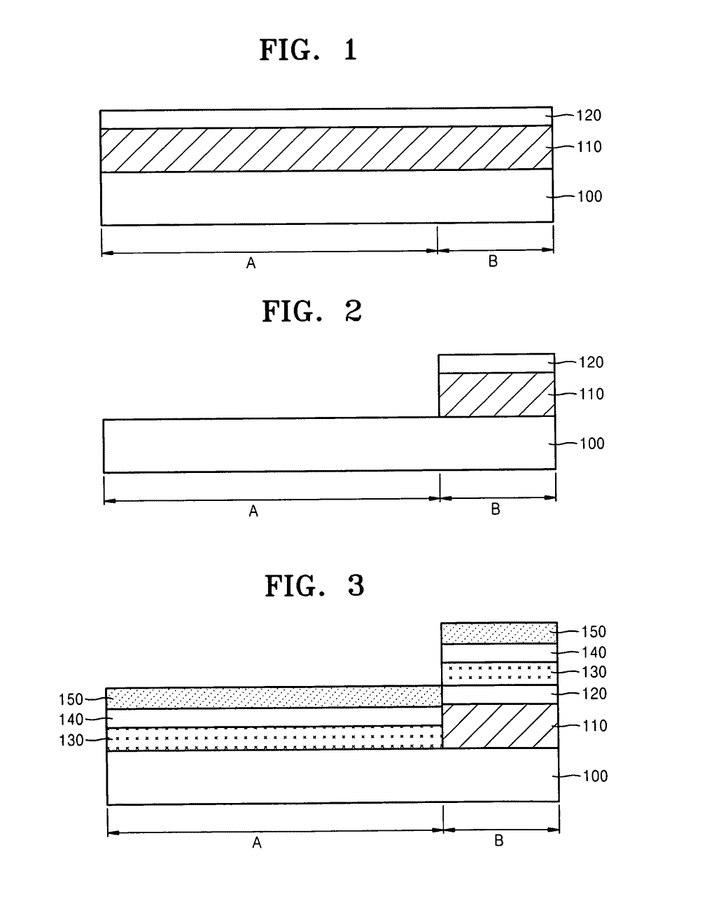

FIGS. 1 through 9 illustrate cross-sectional diagrams of stages in a method of forming a gate electrode of a semiconductor device 10 according to an embodiment.

In the present embodiment, the semiconductor device 10 may be a NAND flash memory, and hereinafter, a method of manufacturing a gate of the NAND flash memory is described with reference to FIGS. 1-9. However, the present embodiment is not limited thereto, and may be applied to form a gate of other semiconductor devices. For example, the present embodiment may be applied to form a control gate in a semiconductor device having a floating gate.

Referring to FIG. 1, a first polysilicon layer 110 may be formed on a substrate 100 including a memory cell region A and a peripheral circuit region B, and then, a barrier layer 120 may be formed on the first polysilicon layer 110. An insulating layer (not illustrated) may be further interposed between the substrate 100 and the first polysilicon layer 110 in another implementation. For example, the insulating layer may include SiO₂.

Referring to FIG. 2, the first polysilicon layer 110 and the barrier layer 120 formed in the memory cell region A of the substrate 100 may be patterned to remove the first polysilicon layer 110 and the barrier layer 120, thereby having the first polysilicon layer 110 and the barrier layer 120 only in the peripheral circuit region B. More specifically, a photoresist pattern (not illustrated) exposing the memory cell region A may be formed to remove the first polysilicon layer 110 and the barrier layer 120 in the memory cell region A.

Since the first polysilicon layer 110 and the barrier layer 120 are removed from the memory cell region A, a full silicide layer may be formed in the memory cell region A in a subsequent stage. In addition, since the first polysilicon layer 110 and the barrier layer 120 are not removed from the peripheral circuit region B, a partial silicide layer sequentially including the first polysilicon layer 110, the barrier layer 120, and a silicide layer (190 in FIG. 9) may be formed in the peripheral circuit region B in a subsequent stage.

The substrate 100 may be a semiconductor substrate and may include any one of, e.g., silicon, a silicon-on-insulator, silicon-on-sapphire, germanium, silicon-germanium, or gallium-arsenide. In addition, the substrate 100 may be a p-type substrate, in which a p-type impurity, e.g., boron (B), is partially injected thereto, or an n-type substrate, in which an n-type impurity, e.g., arsenic (As), is partially injected thereto.

The memory cell region A is a region of the substrate 100 where a plurality of memory cell transistors may be formed, and the peripheral circuit region B is a region of the substrate 100 where peripheral circuits including a plurality of NMOS transistors and a plurality of PMOS transistors may be formed.

The first polysilicon layer 110 may be used to form the plurality of NMOS transistors and the plurality of PMOS transistors in the peripheral circuit region B. The first polysilicon layer 110 may be formed of, e.g., a crystalline doped in an N-type or amorphous silicon. In another implementation, a conductive layer may be used instead of the first poly-silicon layer 110.

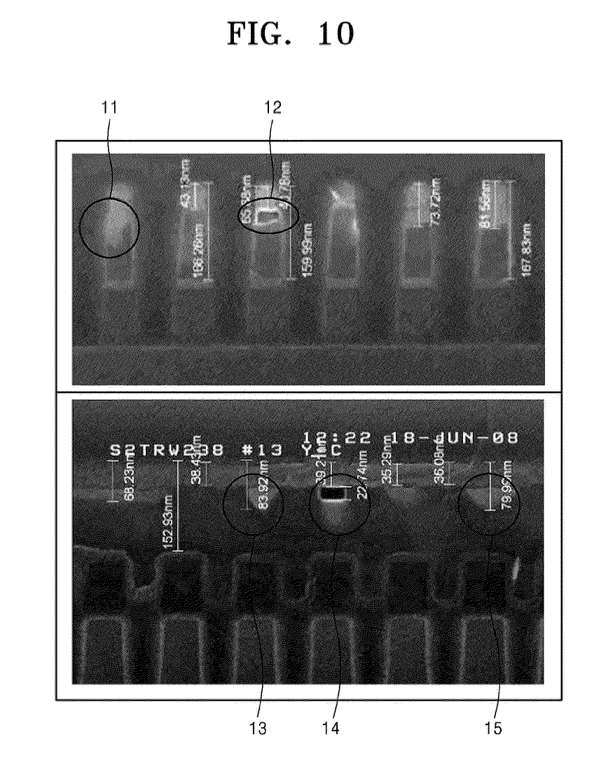

The barrier layer 120 may prevent overgrowth of a silicide layer (190 in FIG. 9), which will be formed in a subsequent stage, and may form an ohmic contact between the first polysilicon layer 110 and the silicide layer. Here, the barrier layer 120 may include a material, e.g., a metal nitride or tungsten silicide (WSiₓ). Since the barrier layer 120 is interposed between the first polysilicon layer 110 and the silicide layer, an equivalent oxide thickness (EOT) of the barrier layer 120 may be reduced and a leakage current may be also reduced. The barrier layer 120 will be described in more detail with reference to FIGS. 10-12.

Referring to FIG. 3, a tunneling insulation layer 130, an electric charge storing layer 140, and a blocking insulation layer 150 may be sequentially formed on the substrate 100 of the memory cell region A and on the barrier layer 120 in the peripheral circuit region B.

The tunneling insulation layer 130 may be formed on the substrate 100 of the memory cell region A and on the upper surface of the barrier layer 120 of the peripheral circuit region B. The tunneling insulation layer 130 may be, e.g., a silicon oxide layer, and may have a thickness of about 20 Å to about 70 Å.

The electric charge storing layer 140 may be formed on the tunneling insulation layer 130 in both the memory cell region A and the peripheral circuit region B. For example, the electric charge storing layer 140 may be separately formed in the memory cell region A and in the peripheral circuit region B. The electric charge storing layer 140 may be used as a floating gate, and may be formed of, e.g., a silicon nitride (SiN) layer or a high dielectric layer having a higher dielectric constant (high-k) than that of the silicon nitride (SiN) layer. For example, the electric charge storing layer 140 may be formed of, e.g., a Si₃N₄ layer, a metal oxide layer, a metal nitride layer, or a combination thereof, and may have a thickness of about 40 Å to about 120 Å. The electric charge storing layer 140 may include a trap site (not illustrated) storing electric charges passing through the tunneling insulation layer 130.

The blocking insulation layer 150 may be formed on the electric charge storing layer 140 in both the memory cell region A and the peripheral circuit region B. For example, the blocking insulation layer 150 may be separately formed in the memory cell region A and in the peripheral circuit region B. The blocking insulation layer 150 may be formed of a material having high-k, e.g., Al₂O₃, ZrO₂, or HfO₂. The blocking insulation layer 150 may block the electric charges trapped in the trap site of the electric charge storage layer 140 from moving to a control gate (the silicide layer in the present embodiment), which will be formed on the blocking insulation layer 150 in a subsequent stage. The blocking insulation layer 150 may also block electric charges of the control gate from being injected into the electric charge storing layer 140.

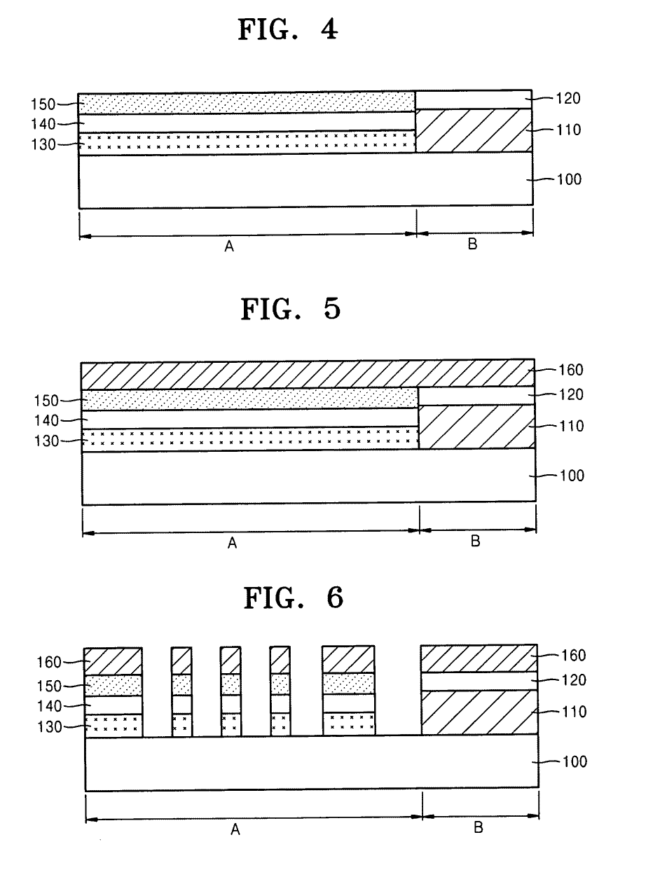

Referring to FIG. 4, the tunneling insulation layer 130, the electric charge storing layer 140, and the blocking insulation layer 150 formed on the barrier layer 120 of the peripheral circuit region B may be removed through patterning. More specifically, a photoresist pattern (not illustrated), exposing the blocking insulation layer 150 formed in the peripheral circuit region B, may remove the tunneling insulation layer 130, the electric charge storing layer 140, and the blocking insulation layer 150 formed on the barrier layer 120 of the peripheral circuit region B. The tunneling insulation layer 130, the electric charge storage layer 140, and the blocking insulation layer 150 formed in the memory cell region A may not be removed.

In another implementation, to prevent the barrier layer 120 from being damaged, an additional polysilicon layer may be further formed on the barrier layer 120 of the peripheral circuit region B. In this case, the additional polysilicon layer formed on the barrier layer 120 may be used as an etching stop layer. In other words, using the additional polysilicon layer formed on the barrier layer 120 of the peripheral circuit region B, the barrier layer 120 may be prevented from being damaged while the tunneling insulation layer 130, the electric charge storing layer 140, and the blocking insulation layer 150, on the barrier layer 120 are removed from the peripheral circuit region B.

Referring to FIG. 5, a second polysilicon layer 160 for silicidation may be formed on the blocking insulation layer 150 of the memory cell region A and the barrier layer 120 of the peripheral circuit region B. The second polysilicon layer 160 may be formed as one single layer extending from the blocking insulation layer 150 of the memory cell region A to the barrier layer 120 of the peripheral circuit region B. The second polysilicon layer 160 may be formed of, e.g., a crystalline doped in an n-type or amorphous silicon.

Referring to FIG. 6, a plurality of gate stack structures, i.e., a plurality of memory cells, may be formed in the memory cell region A by patterning the second polysilicon layer 160, the blocking insulation layer 150, the electric charge storing layer 140, and the tunneling insulation layer 130 formed in the memory cell region A. More specifically, a photoresist pattern exposing a predetermined part of the memory cell region A may be formed, and the second polysilicon layer 160, the blocking insulation layer 150, the electric charge storing layer 140, and the tunneling insulation layer 130 formed on the substrate 100 between the plurality of memory cells may be removed. Further, the second polysilicon layer 160, the blocking insulation layer 150, the electric charge storing layer 140, and the tunneling insulation layer 130 formed on the substrate 100 between the memory cell and the peripheral circuit region B may be removed.

In addition, impurities may be injected into the surface of the substrate 100 exposed on both sides of the plurality of memory cells formed in the memory cell region A, and may be heat treated, thereby forming source/drain regions (not illustrated) on the substrate 100. Moreover, after the plurality of memory cells are formed in the memory cell region A, a cleansing process may be performed.

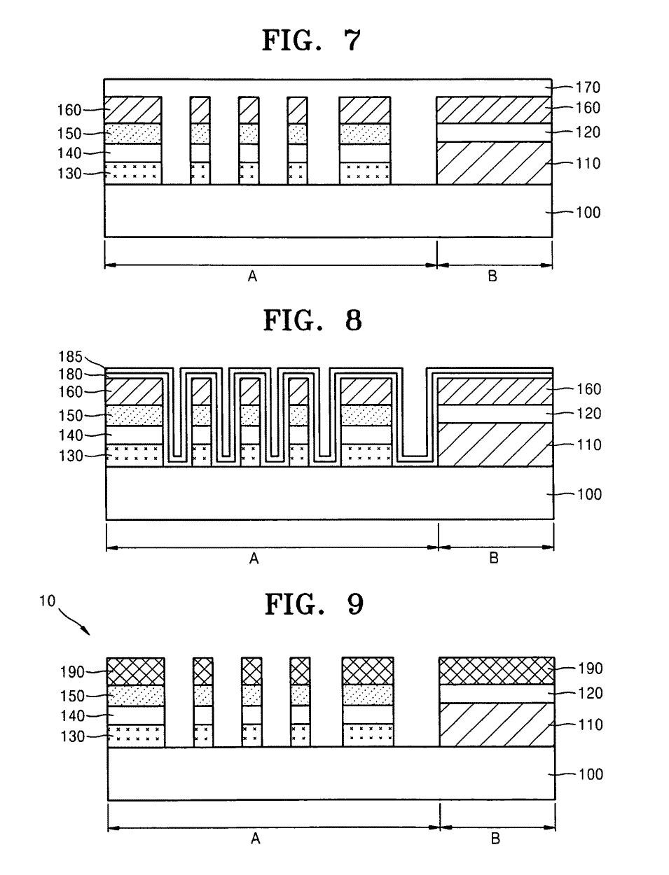

Referring to FIG. 7, an oxidation process, i.e., a gate poly oxide (GPoₓ) process, by which an oxide layer 170 is formed on the plurality of memory cells formed in the memory cell region A and the upper part of the second polysilicon layer 160 in the peripheral circuit region B, may be performed. The oxide layer 170 may be also formed between adjacent memory cells and between the memory cell and the peripheral circuit region B. In another implementation, the oxide layer 170 may be selectively formed on the plurality of memory cells formed in the memory cell region A and the upper part of the second polysilicon layer 160 in the peripheral circuit region B. Since an oxidation process is performed before a silicidation process, the results and reliability of the oxidation process may be better than that in a conventional method.

More specifically, the regions between the memory cells in the memory cell region A may be filled with oxides, e.g., the oxide layer 170, for isolation between the memory cells and for protection of activation regions. For example, thermal oxidation or radical oxidation may be used to fill the regions between the memory cells with the oxides, e.g., the oxide layer 170. Then, the oxides filled in the regions between the memory cells, e.g., the oxide layer 170, may be removed by chemical mechanical polishing (CMP) or dry etch back.

In the radical oxidation, H⁺, O⁻, or OH⁻ radicals with very high activity may be used. The radical oxidation may be fast in the beginning, but the oxidation reaction may slow down when an oxide layer 170 is formed. This is because a mean free path is short in the radical oxidation so that an oxidizing power rapidly decreases when the oxide layer 170 is once formed. Due to such characteristic, a predetermined thickness of the oxide layer 170 may be uniform in the memory cell region A and in the peripheral circuit region B, even though the oxide layer 170 may be formed on bulk-formed polysilicon with a non-uniform crystal lattice direction and a non-uniform grain boundary formed by two different bulk polysilicon making contact during the radical oxidation.

Referring to FIG. 8, a metal layer 180 and a capping layer 185 may be sequentially formed on the memory cells in the memory cell region A and the upper part of the second polysilicon layer 160 formed in the peripheral circuit region B. The metal layer 180 and the capping layer 185 may be formed on sidewalls of the memory cells in the memory cell region A, as well as on the substrate 100 between two adjacent memory cells and a region between the memory cell and the peripheral circuit region B. Further, the metal layer 180 and the capping layer 185 may be formed on a sidewall of the peripheral circuit region facing the memory cell region A. The metal layer 180 may be formed of a low-resistant metal for silicide and may be, e.g., a metal such as titanium (Ti), tungsten (W), cobalt (Co), or nickel (Ni), or an alloy including metals such as platinum (Pt) and rhenium (Re). The capping layer 185 may be a complex layer, e.g., a TiN layer or a Ti/TiN layer.

In this case, the metal layer 180 may be formed on the upper surface of the second polysilicon layer 160, but may not be limited thereto, and the metal layer 180 and the capping layer 185 may be formed on the oxide layer 170.

Referring to FIG. 9, a silicidation process may be performed between the second polysilicon layer 160 and the metal layer 180 formed in the memory cell region A and the peripheral circuit region B, thereby forming a silicide layer 190.

More specifically, a first silicidation process may be performed by heat-treating the metal layer 180 to cause a reaction between the second polysilicon layer 160 and the metal layer 180. In this case, the metal layer 180 may be heat treated at a temperature of about 250° C. to about 550° C. using a device for rapid thermal processing (RTP) or a furnace so that the second polysilicon layer 160 and the metal layer 180 may react to each other and form the silicide layer 190.

Then, the capping layer 185 and a portion of metal layer 180 that did not react in the first silicidation process, may be removed. More specifically, a portion of the metal layer 180 formed on the substrate 100 between the adjacent memory cells and a portion of the metal layer 180 formed between the memory cell and the peripheral circuit region B may be removed along with the capping layer 185.

Next, a second silicidation process may be performed by heat-treating the remaining metal layer 180, e.g., a portion on the second polysilicon layer 160 and on a side of the second polysilicon layer 160, to cause a reaction between the second polysilicon layer 160 and the metal layer 180 formed on the memory cells in the memory cell region A and between the second polysilicon layer 160 and the metal layer 180 formed in the peripheral circuit region B. In this case, the metal layer 180 may be heat treated at a temperature of about 400° C. to about 850° C. using a device for RTP or a furnace so that the second polysilicon layer 160 and the metal layer 180 may react to each other and form the silicide layer 190.

As described above, since a gate electrode is formed as the silicide layer 190 on each memory cell in the memory cell region A and on the peripheral circuit region B, a resistance of the gate electrode decreases, and thus, an operation speed of the memory cells may increase. Also, since the gate electrode is formed as a full silicide layer, a characteristic of the memory cells may be improved since a depletion layer is not formed, a capacity reduction of the blocking insulation layer 150 may be prevented, and a coupling ratio may be increased.

FIG. 10 illustrates a silicide layer formed in a peripheral circuit region when SiN is used to form a barrier layer. Referring to FIG. 10, when a dielectric substance, e.g., SiN, is used to form the barrier layer, extrusions, e.g., portions 11, 13, and 15, may be seen in the silicide layer formed in the peripheral circuit region. Also, voids, e.g., portions 12 and 14, may be seen in the silicide layer formed in the peripheral circuit region. As such, when SiN is used to form the barrier layer, the barrier layer may not prevent overgrowth of the silicide layer and may not provide an ohmic contact between the polysilicon layer formed below the barrier layer and the silicide layer formed above the barrier layer.

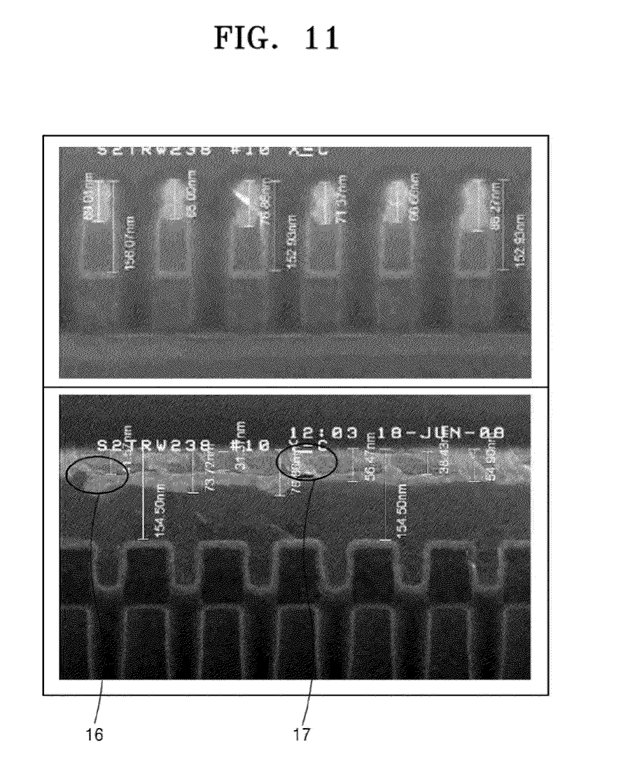

FIG. 11 illustrates a silicide layer formed in a peripheral circuit region when SiO₂ is used to form a barrier layer. Referring to FIG. 11, when a dielectric substance, e.g., SiO₂, is used to form the barrier layer, extrusions, e.g., a portion 16, may be seen, and a void, e.g., a portion 17, may be seen in the silicide layer formed in the peripheral circuit region. As such, when SiO₂ is used to form the barrier layer, the barrier layer may not prevent overgrowth of the silicide layer and may not provide an ohmic contact between the poly-silicon layer formed below the barrier layer and the silicide layer formed above the barrier layer.

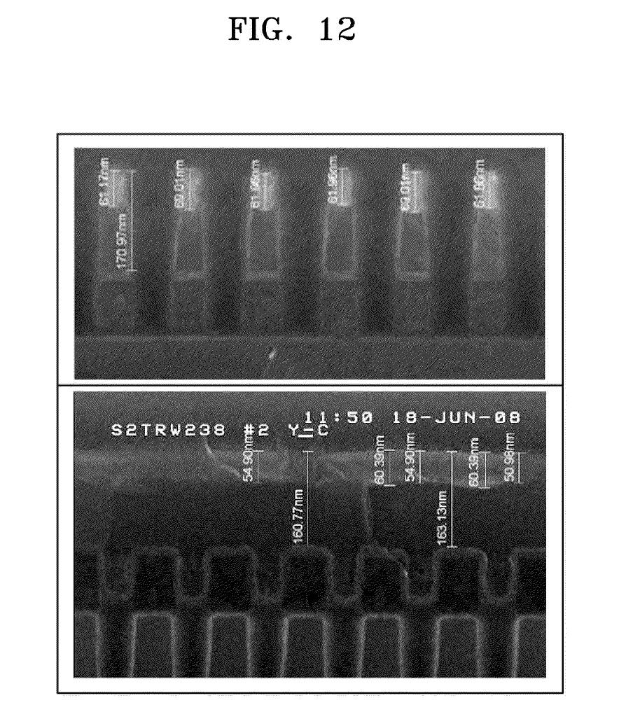

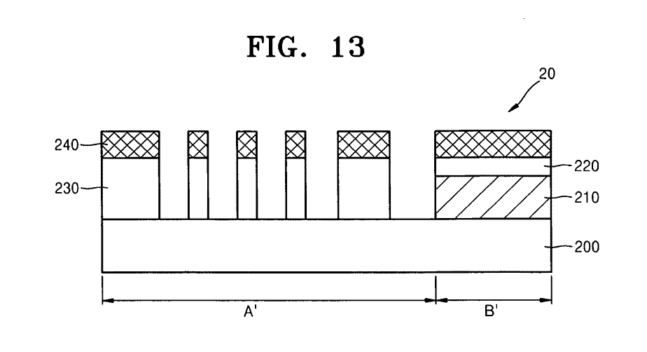

FIG. 12 illustrates a silicide layer formed in a peripheral circuit region when tungsten silicide (WSiₓ) is used to form a barrier layer. Referring to FIG. 12, when WSiₓ is used to form the barrier layer, extrusions or voids may not be seen in the silicide layer formed in the peripheral circuit region. As such, when WSiₓ is used to form the barrier layer, the barrier layer may prevent overgrowth of the silicide layer and may provide an ohmic contact between the poly-silicon layer formed below the barrier layer and the silicide layer formed above the barrier layer.

FIG. 13 illustrates a cross-sectional diagram of a semiconductor device 20 according to an embodiment. Referring to FIG. 13, the semiconductor device 20 may include a substrate 200 including a memory cell region A′ and a peripheral circuit region B′, a plurality of memory cells formed in the memory cell region A′, and at least one transistor formed in the peripheral circuit region B′. The semiconductor device 20 may be a NAND flash memory device. However, the present embodiment is not limited thereto, and may be applied to other semiconductor devices.

The plurality of memory cells formed in the memory cell region A′ may respectively include a stack structure 230 and a silicide layer 240. As such, gate electrodes of the memory cell region A′ formed of a full silicide layer may not include a polysilicon layer, which is not silicide. The stack structure 230 may include a floating gate, and the silicide layer 240 may be operated as a control gate. More specifically, the stack structure 230 may include a tunneling insulation layer, an electric charge storing layer, and a blocking insulation layer.

The at least one transistor formed in the peripheral circuit region B′ may include a polysilicon layer 210, a barrier layer 220, and the silicide layer 240. As such, the gate electrode of the peripheral circuit region B′ may be formed of a partial silicide layer including the polysilicon layer 210, which is not silicided. The barrier layer 220 may include a metal nitride or tungsten silicide (WSiₓ) so that the barrier layer 220 may prevent overgrowth of the silicide layer 240 and provide an ohmic contact between the polysilicon layer 210 and the silicide layer 240.

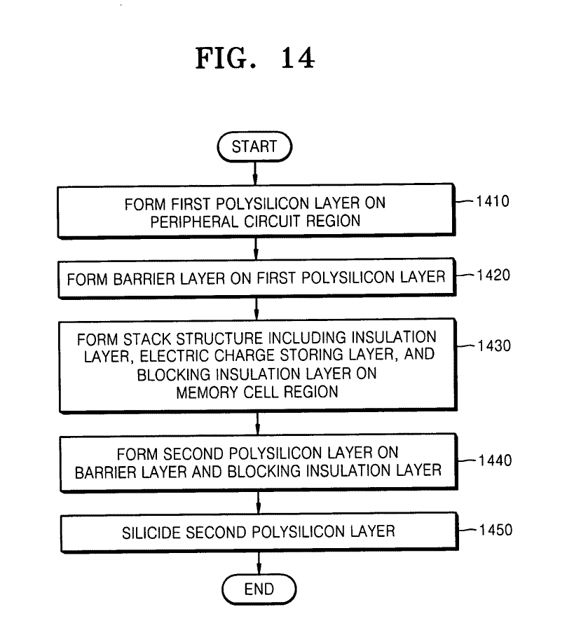

FIG. 14 illustrates a flowchart illustrating a method of forming a gate electrode of a semiconductor device according to an embodiment. Referring to FIG. 14, a first polysilicon layer may be formed on a peripheral circuit region disposed on a substrate in operation 1410. In operation 1420, a barrier layer providing an ohmic contact may be formed on the first polysilicon layer. More specifically, the barrier layer may include metal nitride or tungsten silicide (WSiₓ). In another embodiment, forming a third polysilicon layer on the barrier layer for etching prevention of the barrier layer may be further included.

In operation 1430, a stack structure including a tunneling insulation layer, an electric charge storing layer, and a blocking insulation layer may be formed in a memory cell region of the substrate. The electric charge storing layer may include SiN, and the blocking insulation layer may include at least one of Al₂O₃, ZrO₂, and HfO₂.

In operation 1440, a second polysilicon layer may be formed on the barrier layer, on the blocking insulation layer of the peripheral circuit region, and on the memory cell region, respectively. In operation 1450, the second polysilicon layer may be silicided to form a silicide gate electrode. More specifically, a full silicide gate electrode may be formed in the memory cell region, and a partial silicide gate electrode may be formed in the peripheral circuit region. In another implementation, filing an oxide in the region between the plurality of cells and removing the oxide may be further included between operation 1440 and operation 1450.

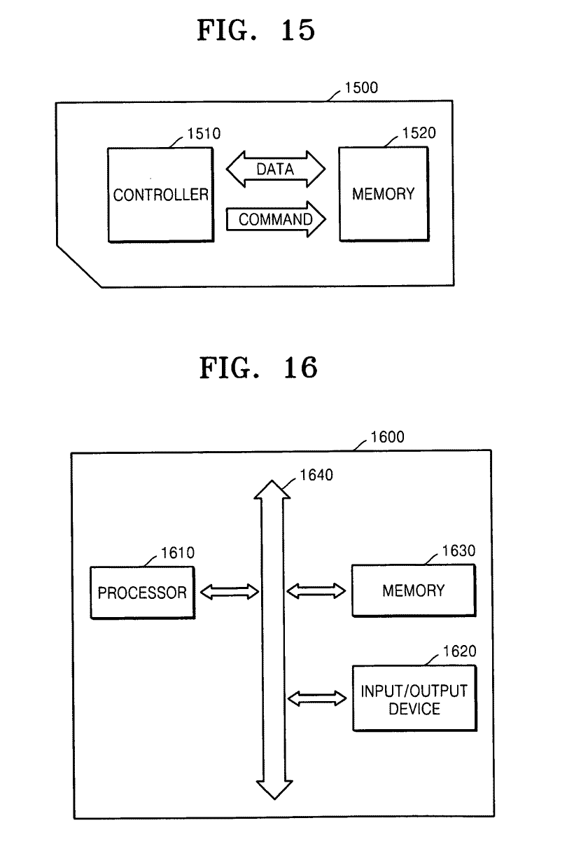

FIG. 15 schematically illustrates a card 1500 according to an embodiment. Referring to FIG. 15, the card 1500 may include a controller 1510 and a memory 1520, which are arranged to exchange an electric signal. For example, when the controller 1510 outputs a command signal, the memory 1520 may transmit data. The memory 1520 may include the memory device illustrated in FIG. 13. The card 1500 may be used in a memory device, e.g., a memory stick card, a smart media (SM) card, a secure digital (SD) card, a mini secure digital (SD) card, or a multi media card (MMC).

FIG. 16 schematically illustrates a system 1600 according to an embodiment. Referring to FIG. 16, a processor 1610, an input/output device 1620, and a memory 1630 included in the system 1600 may communicate with each other via a bus 1640. The processor 1610 may execute a program and may control the system 1600. The input/output device 1620 may be used to input or output data of the system 1600. The system 1600 may be connected to an external device, e.g., a personal computer or a network, using the input/output device 1620 and may exchange data with the external device. The memory 1630 may include the memory device of FIG. 13. For example, the memory 1630 may store codes and data for operating the processor 1610. For example, the system 1600 may be used in mobile phones, MP3 players, navigations, portable multimedia players (PMP), solid state disks (SSD), or household appliances.

The embodiments may also be embodied as computer readable codes on a computer readable recording medium. The computer readable recording medium may be any data storage device that can store data and thereafter be read by a computer system. Examples of the computer readable recording medium include read-only memory (ROM), random-access memory (RAM), CD-ROMs, digital versatile discs (DVD), magnetic tapes, floppy disks, optical data storage devices, and flash memory. The computer readable recording medium may also be distributed over network coupled computer systems so that the computer readable code may be stored and be executed in a distributed fashion. The program or code stored in the recording medium may denote a series of instructions used directly or indirectly in information processor by the computer to obtain specific result. Therefore, the term ‘computer’ generally denotes all devices having information processing capability for executing specific functions by the program and includes a memory, an input/output device, and an arithmetic unit.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of forming a gate electrode of a semiconductor device, the method comprising:
forming a first polysilicon layer in a peripheral circuit region of a substrate;
forming a barrier layer on the first polysilicon layer, the barrier layer providing an ohmic contact;
forming a stack structure including a tunneling insulation layer, an electric charge storing layer, and a blocking insulation layer in a memory cell region of the substrate;
forming a second polysilicon layer on the barrier layer and the blocking insulation layer; and
siliciding the second polysilicon layer and forming a silicide gate electrode.

2. The method as claimed in claim 1, wherein the forming of the silicide gate electrode includes forming a full silicide gate electrode in the memory cell region and forming a partial silicide gate electrode in the peripheral circuit region.

3. The method as claimed in claim 2, further comprising forming a plurality of memory cells by patterning the second polysilicon layer, the blocking insulation layer, the electric charge storing layer, and the tunneling insulation layer formed in the memory cell region.

4. The method as claimed in claim 3, wherein the forming of the full silicide gate electrode includes:
forming a metal layer on the plurality of memory cells; and
heat-treating the metal layer and forming the full silicide gate electrode by a reaction between the second polysilicon layer and the metal layer.

5. The method as claimed in claim 4, wherein the heat-treating of the metal layer and forming of the full silicide gate electrode by a reaction between the second polysilicon layer and the metal layer includes:
first heat-treating the metal layer at temperature of about 250° C. to about 550° C.;
removing the metal layer that does not react in the first heat-treating; and
second heat-treating the metal layer at a temperature of about 400° C. to about 850° C. and thereby forming the full silicide gate electrode by a reaction between the second polysilicon layer and the metal layer.

6. The method as claimed in claim 5, wherein the metal layer that does not react in the first heat-treating includes portions of the metal layer that are on the substrate between adjacent memory cells as well as the portion between the memory cell and the peripheral circuit region.

7. The method as claimed in claim 4, wherein the electric charge storing layer includes SiN, the blocking insulation layer includes at least one of Al₂O₃, ZrO₂, and HfO₂, and the metal layer includes at least one of Ti, W, Co, Ni, Pt, and Re.

8. The method as claimed in claim 2, wherein the forming of the partial silicide gate electrode includes:
forming a metal layer on the second polysilicon layer formed in the peripheral circuit region; and
heat-treating the metal layer and forming the partial silicide gate electrode by a reaction between the second polysilicon layer and the metal layer.

9. The method as claimed in claim 2, wherein the barrier layer includes metal nitride or tungsten silicide (WSiₓ).

10. The method as claimed in claim 2, further comprising a third polysilicon layer on the barrier layer for etching prevention.

11. The method as claimed in claim 3, further comprising:
performing an oxidation process by filling spaces between the plurality of memory cells with oxides; and
removing the oxides.

12. The method as claimed in claim 11, wherein the oxidation process is performed before siliciding the second polysilicon layer.

13. The method as claimed in claim 8, wherein the electric charge storing layer includes SiN, the blocking insulation layer includes at least one of Al₂O₃, ZrO₂, and HfO₂, and the metal layer includes at least one of Ti, W, Co, Ni, Pt, and Re.

14-18. (canceled)
